(19) United States
(12) Patent Application Publication
(10) Pub. No.: US 2002/0167048 A1
(43) Pub. Date: Nov. 14, 2002

(54) Enhanced mobility NMOS and PMOS transistors using strained Si/SiGe layers on silicon-on-insulator substrates

(76) Inventors: Douglas J. Tweet, Camas, WA (US); Sheng Teng Hsu, Camas, WA (US)

Correspondence Address: Matthew D. Rabdau, Patent Attorney, Sharp Laboratories of America, Inc., 5750 NW Pacific Rim Boulevard, Camas, WA, 98607, US

(21) Appl. No.: 09/855,392

(22) Filed: May 14, 2001

(51) Int. Cl. H01L 21/00; H01L 21/84; H01L 27/01

(52) U.S. Cl. 257/347; 257/350; 438/149; 438/151

(57) ABSTRACT

The present invention comprises a thin Si/SiGe stack on top of an equally thin top Si layer of a SOI substrate. The SiGe layer is compressively strained but partially relaxed and the Si layers are each tensily strained, without high dislocation densities. The silicon layer of the SOI substrate has a thickness of approximately 10 to 40 nm. The SiGe layer has a thickness of approximately 5 to 50 nm. The top, second Si layer has a thickness of approximately 2 to 50 nm. Part of the top Si layer may be thermally oxidized to form a gate dielectric for MOS applications.

### FIELD OF THE INVENTION

This invention relates to enhanced NMOS and PMOS transistors using strained Si/SiGe layers on silicon-on-insulator substrates and, more particularly, to NMOS and PMOS transistors including compressively strained, but partially relaxed, SiGe and tensily strained Si layers having low dislocation densities.

### BACKGROUND OF THE INVENTION

During the past decade a number of different device structures based on silicon germanium (SiGe) technology were developed to produce field effect transistors (FET) with enhanced mobilities. One design for a p-channel metal oxide semiconductor (PMOS) transistor includes a buried, pseudomorphically strained SiGe layer capped by an unstrained silicon (Si) layer. The silicon cap layer is partially oxidized to form a gate dielectric. Due to an offset in the valence band, the holes can be confined to the SiGe channel. This enhances the mobility in two ways: by the intrinsic properties of the strained SiGe layer; and, by separating the holes from the silicon dioxide/silicon (SiO₂/Si) interface, thereby reducing surface scattering. In this design, dislocations in the SiGe film can be avoided if the SiGe film thickness is made very thin. Fabrication of this device is compatible with state-of-the art complementary metal oxide semiconductor (CMOS) processing. However, since there is virtually no offset between the Si film and the strained SiGe film at the conduction band, this design offers no advantage for n-channel metal oxide semiconductor (NMOS) devices and may actually worsen performance.

Compressively strained SiGe and tensily strained Si films can be used to make p-channel modulation doped field effect transistor (p-MODFET) and n-channel modulation doped field effect transistor (n-MODFET) devices with greatly enhanced hole and electron mobilities, respectively. However, these designs require graded, relaxed SiGe buffer layers as “virtual” substrates. The dislocation densities in these buffers are seven orders of magnitude too high for large-scale production feasibility.

Pseudomorphic SiGe PMOS devices have been proposed and fabricated on SOI material, giving significantly enhanced hole mobilities. In two separate fabricated devices, the top Si layer of the SOI substrate has been quite thick, 150 nm and 50 nm, respectively.

Accordingly, there is a need for a device that provides both compressively strained SiGe and tensily strained Si layers without the high dislocation densities found in graded, relaxed SiGe buffer layers. If such a device could be fabricated, then both hole and electron mobilities could be enhanced.

### SUMMARY OF THE INVENTION

Below the “critical thickness” for dislocation generation and propagation, SiGe layers can be grown “pseudomorphically” to a bulk Si substrate. This means the layer is epitaxially strained to the substrate. Any Si then grown on top of this SiGe layer is consequently relaxed, with no strain. However, if the SiGe could be grown on an extremely thin Si substrate, of a thickness comparable to the SiGe layer, both the SiGe layer and Si layer would be strained, without dislocations. Essentially, the total strain would be shared between the SiGe and the Si layers. Another effect would be that the SiGe critical thickness would be increased. Additionally, a Si layer grown on top of the SiGe would be tensily strained.

The closest thing available to such a thin Si substrate is the top Si layer in a silicon-on-insulator (SOI) substrate. The increased defect density of SOI substrates, compared to bulk silicon substrates, may promote strain relaxation. It may then be expected that when growing a thin Si/SiGe stack on top of an equally thin top Si layer of a SOI substrate that the SiGe will be compressively strained and the Si layers will be tensily strained, without high dislocation densities.

Accordingly, the present invention comprises a thin Si/SiGe stack on top of an equally thin top Si layer of a SOI substrate. The SiGe layer is compressively strained, but partially relaxed, and the Si layers are each tensily strained, without high dislocation densities. The silicon layer of the SOI substrate has a thickness of approximately 10 to 40 nm. The SiGe layer has a thickness of approximately 5 to 50 nm. The top, second Si layer has a thickness of approximately 2 to 50 nm.

Accordingly, an object of the invention is to provide enhanced NMOS and PMOS transistors using strained Si/SiGe layers on silicon-on-insulator substrates.

Another object of the invention is to provide enhanced NMOS and PMOS transistors including compressively strained SiGe and tensily strained Si layers having low dislocation densities.

A further object of the invention is to provide enhanced NMOS and PMOS transistors having enhanced hole and electron mobilities.

### BRIEF DESCRIPTION OF THE DRAWINGS

FIG. 1 is a schematic of the device of the present invention.

FIG. 2 is a flowchart of the method of the present invention.

### DETAILED DESCRIPTION OF THE PREFERRED EMBODIMENTS

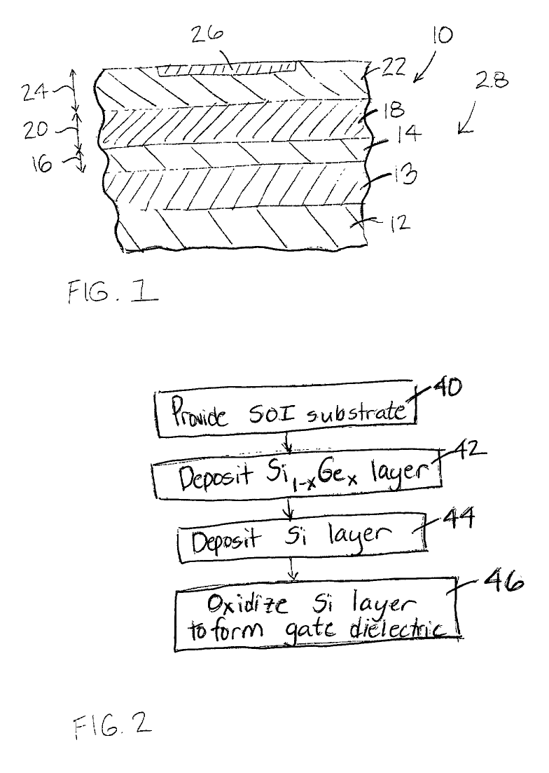

FIG. 1 shows device 10 of the present invention. Device 10 includes a silicon-on-insulator (SOI) substrate 12 prepared with a buried oxide (BOX) 13, and a top-Si layer 14 being as thin as possible, typically having a thickness 16 of about 10-40 nM. Next, an epitaxial Si₁₋ₓ Geₓ film 18 is deposited, with x being any value from 0.1 to 0.5 or higher, such as in a range of 0.1 to 0.9, if possible. The thickness 20 of film 18 must be kept thin enough to avoid dislocation generation and/or propagation, i.e., to maintain the dislocation generation and/or propagation below a threshold value of 100/cm². Those skilled in the art will understand that this value depends on the recommended Semiconductor Industry Association (SIA) values, which vary for each generation of device. Another way of determining the acceptable thickness of film 18 is that the thickness must be kept thin enough to ensure a dislocation density no higher than that of the SOI Silicon starting substrate. Thickness 20 typically ranges from 5 to 50 n. Another layer of epitaxial Si 22 is then deposited on the SiGe layer. Layer 22 has an appropriate thickness 24, typically from 2 to 50 nm. Part of this last Si layer may be thermally oxidized to form a gate dielectric 26 for MOS applications.

The SiGe and Si layers, 18 and 22 respectively, can be deposited by any of the standard epitaxial methods, such as low pressure chemical vapor deposition (LPCVD), ultra high vacuum chemical vapor deposition (UHVCVD), rapid thermal chemical vapor deposition (RTCVD), or molecular beam epitaxy (MBE). The Si/SiGe layers can be grown with either selective or non-selective chemistries on either patterned or un-patterned substrates.

Both the sharing of strain between SiGe layer 18 and substrate Si layer 14, and the capping of SiGe layer 18 with Si layer 22, increases the effective critical thickness of the entire stack 28. The “effective critical thickness” is the critical thickness for dislocation generation. Its increase depends on the amount of relaxation of the SiGe. Consequently, thicker SiGe layers or layers with higher Ge concentrations could be grown. For example, the SiGe layer may have a Ge concentration of 0.3 or a thickness of 50 nm. Layers having higher concentrations of germanium would result in higher hole and electron mobilities. For example, accordingly to published experimental results, a device having a germanium concentration of 0.3 would have an field effective electron mobility of approximately 500 cm²/V-sec. Similarly, a device having a germanium concentration of 0.3 would have a field effective hole mobility of approximately 250 cm²/V-sec.

Due to the thicknesses of the deposited layers, the substrate silicon layer 14 is tensily strained, the silicon germanium layer 18 is compressively strained, and the top silicon layer 22 is tensily strained. The explanation for the strain of the three layers can be explained as follows. Silicon layer 14 is partially de-coupled from substrate 12 by buried oxide layer 13. Accordingly, silicon layer 14 is somewhat free to relax when the SiGe layer 18 is grown on top of silicon layer 14. If this happens to silicon layer 14 and SiGe layer 18, then the silicon layer 22 grown on top of SiGe layer 18 will be tensily strained. In other words, by growing SiGe layer 18 on the SOI, the strain will be shared between SiGe layer 18 and substrate silicon layer 14. This will result in the SiGe layer being compressively strained, but partially relaxed. Substrate silicon layer 14 will be tensily strained. Then, the additional silicon cap layer 22 is grown on SiGe layer 18 wherein cap layer 22 will be tensily strained. In NMOS devices, the silicon cap layer 22 can be used as a channel. In PMOS devices, the silicon cap layer 22 or the SiGe layer 18 can be used as a channel.

FIG. 2 shows a flowchart of the process steps of the present invention. Step 40 comprises providing a silicon-on-insulator substrate having a silicon layer therein. Step 42 comprises depositing a SiGe layer on the silicon-on-insulator substrate. Step 44 comprises depositing a silicon layer on the SiGe layer. Step 46 comprises oxidizing a section of the top silicon layer to form a gate dielectric. The process results in a layered structure 28 having a partially relaxed, compressively strained SiGe layer and tensily strained Si layers having low dislocation densities. The layered structure also provides enhanced hole and electron mobilities.

The same or very similar structures could be used for both n-channel and p-channel devices, with the last Si layer 22 acting as the channel for electrons and the SiGe layer 18 acting as the channel for holes. Silicon cap layer 22 could also be used as the channel for both electrons or holes. Either CMOS or MODFET designs could be used. Moreover, the structure and fabrication processes are compatible with those of standard CMOS structures and fabrication steps. Alternatively, silicon germanium carbon (SiGeC) layers may also be used as part of this structure.

Thus, a transistor using strained Si/SiGe layers on a silicon-on-insulator substrate, and a method of fabricating the same, has been disclosed. Although preferred structures and methods of fabricating the device have been disclosed, it should be appreciated that further variations and modifications may be made thereto without departing from the scope of the invention as defined in the appended claims.

We claims:

1. A metal oxide semiconductor transistor comprising:
a silicon-on-insulator substrate including a substrate silicon layer therein;
a silicon germanium layer positioned on said substrate silicon layer; and
a top silicon layer positioned on said silicon germanium layer, wherein said silicon germanium layer is compressively strained and said top silicon layer and said substrate silicon layer are both tensily strained,
wherein said substrate silicon layer has a thickness in a range of 10 to 40 nm.

2. The transistor of claim 1 wherein said transistor has a dislocation density no greater than a dislocation density of the substrate silicon layer.

3. The transistor of claim 1 wherein said silicon germanium layer has a thickness in a range of 5 to 50 nm.

4. The transistor of claim 1 wherein said silicon germanium layer comprises Si₁₋ₓGeₓ, wherein x is in a range of 0.1 to 0.9.

5. The transistor of claim 1 wherein said silicon germanium layer comprises Si₁₋ₓGeₓ, wherein x is in a range of 0.1 to 0.5.

6. The transistor of claim 1 wherein said top silicon layer has a thickness in a range of 2 to 50 nm.

7. The transistor of claim 1 wherein said top silicon layer includes a gate dielectric region.

8. The transistor of claim 1 wherein said transistor has a field effective electron mobility of at least 500 cm²/V-sec.

9. A metal oxide semiconductor transistor comprising:
a silicon-on-insulator substrate including a substrate silicon layer therein;
a silicon germanium layer positioned on said substrate silicon layer; and
a top silicon layer positioned on said silicon germanium layer, wherein said substrate silicon layer has a thickness in a range of 10 to 40 nm, said silicon germanium layer has a thickness in a range of 5 to 50 nm, and said top silicon layer has a thickness in a range of 2 to 50 nm.

10. The transistor of claim 9 wherein said silicon germanium layer comprises Si₁₋ₓGeₓ, wherein x is in a range of 0.1 to 0.5.

11. The transistor of claim 9 wherein said top silicon layer includes a gate dielectric region.

12. The transistor of claim 9 wherein said transistor has a field effective electron mobility of at least 500 cm²/V-sec.

13. The transistor of claim 9 wherein said silicon germanium layer is partially relaxed and compressively strained and said top silicon layer and said substrate silicon layer are both tensily strained.

14. The transistor of claim 9 wherein said transistor comprises a NMOS transistor.

15. The transistor of claim 9 wherein said transistor comprises a PMOS transistor.

16. A method of fabricating a transistor having enhanced mobility, comprising the steps of:
providing a silicon-on-insulator substrate including a substrate silicon layer having a thickness in a range of 10 to 40 nm;
depositing a silicon germanium layer on said substrate silicon layer, wherein said silicon germanium layer has a thickness in a range of 5 to 50 nm; and
depositing a top silicon layer on said silicon germanium layer, wherein said top silicon layer has a thickness in a range of 2 to 50 nm.

17. The method of claim 16 wherein said silicon germanium layer is deposited so as to be compressively strained, and said top silicon layer and said substrate silicon layer are deposited so as to both be tensily strained.

18. The method of claim 16 wherein said silicon germanium layer comprises Si₁₋ₓGeₓ, and wherein x is in a range of 0.1 to 0.9.

19. The method of claim 16 further comprising forming a gate dielectric region in said top silicon layer.

20. The method of claim 16 wherein said method produces a transistor having a field effective electron mobility of at least 500 cm²/V-sec, and a dislocation density no greater than a dislocation density of the substrate silicon layer initially provided.

21. The transistor of claim 1 wherein said transistor has a field effective hole mobility of at least 250 cm²/V-sec.
